(19) United States
(12) Patent Application Publication
(10) Pub. No.: US 2025/0377678 A1
(43) Pub. Date: Dec. 11, 2025

(54) OSCILLATION CIRCUIT AND POWER SUPPLY DEVICE

(71) Applicant: ROHM Co., LTD., Kyoto (JP)

(72) Inventor: Shingo Hashiguchi, Kyoto (JP)

(73) Assignee: ROHM Co., LTD., Kyoto (JP)

(21) Appl. No.: 19/206,323

(22) Filed: May 13, 2025

(30) Foreign Application Priority Data
Jun. 7, 2024 (JP) 2024-093085

(51) Int. Cl. G05F 1/56; H03K 3/017

(52) U.S. Cl. CPC G05F 1/56; H03K 3/017

(57) ABSTRACT

Provided is an oscillation circuit including a ramp voltage generation circuit generating a ramp voltage according to a first reference voltage, and a comparator generating a pulse-driven clock signal according to the first reference voltage and the ramp voltage. The ramp voltage generation circuit includes a first signal generation circuit generating a first signal that rises or falls according to a duty ratio of a first pulse width modulation signal generated according to a pulse period of the clock signal, and a second signal generation circuit generating a second signal that rises or falls in a direction opposite to the first signal according to the duty ratio of the first pulse width modulation signal. The ramp voltage generation circuit generates the ramp voltage according to the lowest voltage among a second reference voltage based on the first reference voltage, the first signal, and the second signal.

### CROSS REFERENCE TO RELATED APPLICATIONS

This application claims priority benefit of Japanese Patent Application No. JP 2024-093085 filed in the Japan Patent Office on Jun. 7, 2024. Each of the above-referenced applications is hereby incorporated herein by reference in its entirety.

### BACKGROUND

The technology disclosed in the specification relates to an oscillation circuit and a power supply device.

In the past, there has been a power supply device (for example, a direct current (DC)-DC converter) that varies a voltage on the basis of a clock signal generated by an oscillation circuit.

It should be noted that, as an example of the prior art related to the above, Japanese Patent Laid-Open No. 2022-112806 can be cited.

### BRIEF DESCRIPTION OF THE DRAWINGS

FIG. 1 is a block diagram for depicting a configuration of a power supply device according to a comparison example;

FIG. 2 is a diagram for depicting a configuration of an oscillation circuit;

FIG. 3 is a diagram for depicting an input voltage, an output voltage, and a first pulse width modulation (PWM) signal;

FIG. 4 is a block diagram for depicting a configuration of a power supply device according to the present disclosure;

FIG. 5 is a diagram for depicting a configuration of a pulse period control circuit;

FIG. 6 is a diagram for depicting a configuration of a ramp voltage generation circuit; and

FIG. 7 is a timing chart for depicting a relation between the input voltage and the output voltage.

### DETAILED DESCRIPTION

### <Regarding Power Supply Device Y of Comparison Example>

First, a power supply device Y will be described as a comparison example of a power supply device X of the present disclosure. Next, problems of the comparison example will be described, and then the power supply device X of the present disclosure will be described.

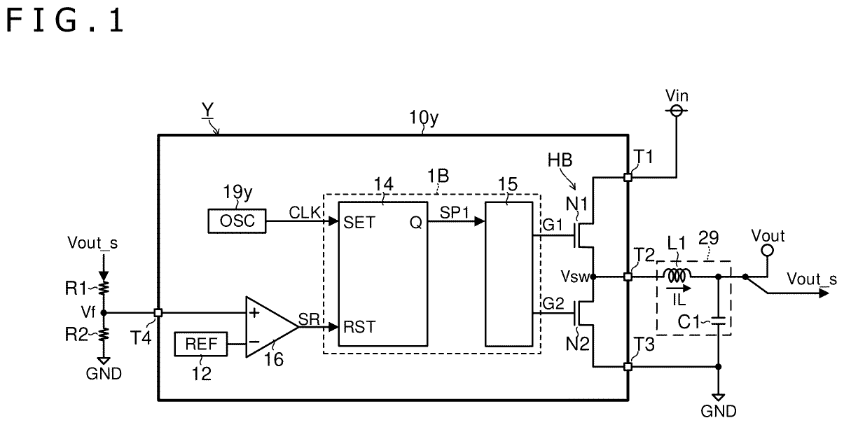

FIG. 1 is a block diagram for depicting a configuration of the power supply device Y according to the comparison example. As depicted in FIG. 1, the power supply device Y is a step-down type DC/DC converter that generates an output voltage Vout from an input voltage Vin to supply it to a load (not illustrated). The power supply device Y has a power supply control device 10y and various discrete components (for example, an inductor L1, a capacitor C1, and resistors R1 and R2).

<Regarding Power Supply Control Device 10y>

The power supply control device 10y is a semiconductor integrated circuit (IC) device (what is generally called a power supply control integrated circuit). The power supply control device 10y includes external terminals T1 to T4 as a section establishing electrical connection with the outside of the device.

The external terminal T1 is connected to an input end of the input voltage Vin. The external terminal T2 is connected to a first end of the inductor L1. A second end of the inductor L1 is connected to an output end of the output voltage Vout together with a first end of the capacitor C1. The external terminal T3 is connected to a ground end GND. A second end of the capacitor C1 is connected to the ground end GND. It should be noted that the potential applied to the ground end GND will be referred to as a ground potential GND (=0 V), in some cases below.

The power supply control device 10y has a switch output stage HB, a comparison voltage generation circuit 12, a reset signal generation circuit 16, an oscillation circuit 19y, and a driver stage 1B.

The switch output stage HB is a half bridge output stage including an output element N1 and a rectifying element N2. Each of the output element N1 and the rectifying element N2 is an N-channel metal-oxide-semiconductor field-effect transistor (MOSFET). The output element N1 and the rectifying element N2 are complementarily switched and driven according to drive signals G1 and G2. It should be noted that the term “complementarily” should be understood in a broad sense to include not only a case where the on/off states of the output element N1 and the rectifier element N2 are completely reversed, but also a case where a simultaneous off period (what is generally called dead time) is provided for both of them.

A drain of the output element N1 is connected to the external terminal T1. Both a source of the output element N1 and a drain of the rectifying element N2 are connected to the external terminal T2. A source of the rectifying element N2 is connected to the external terminal T3. Gates of the output element N1 and the rectifying element N2 are connected to application ends of the drive signals G1 and G2, respectively.

When the drive signal G1 is at a high level and the drive signal G2 is at a low level, the output element N1 is turned on, and the rectifying element N2 is turned off. Then, a current flows in a path from the external terminal T1 to the external terminal T2 via the output element N1, and electric energy is stored in the inductor L1.

Conversely, when the drive signal G1 is at a low level and the drive signal G2 is at a high level, the output element N1 is turned off, and the rectifying element N2 is turned on. Then, a current flows in a path from the external terminal T3 to the external terminal T2 via the rectifying element N2 until the electric energy stored in the inductor L1 is not left.

By repeating such switching drive, a rectangular wave-like switch voltage Vsw appears in the external terminal T2. The DC output voltage Vout can be obtained by smoothing the switch voltage Vsw with use of a smoothing/rectifying circuit 29 configured with the capacitor C1 and the inductor L1.

A first end of the resistor R1 is connected to an output end of the output voltage Vout. A second end of the resistor R1 is connected to the external terminal T4 together with a first end of the resistor R2. A second end of the resistor R2 is connected to the ground end GND. That is, the output voltage Vout is fed back and input to the external terminal T4 via the resistor R1.

The resistor R1 and the resistor R2 configure a voltage dividing circuit. Specifically, a feedback voltage Vf is generated at the connection node between the resistor R1 and the resistor R2. The feedback voltage Vf is determined on the basis of a voltage dividing ratio determined from the resistance value of each of the resistor R1 and the resistor R2 and the output voltage Vout (depicted as Vout s in FIG. 1).

The comparison voltage generation circuit 12 is configured to generate a comparison voltage REF that is a predetermined constant voltage.

The reset signal generation circuit 16 is a comparator. The reset signal generation circuit 16 has an inverting input end (−) and a non-inverting input end (+). The inverting input end (−) of the reset signal generation circuit 16 is connected to the comparison voltage generation circuit 12. The non-inverting input end (+) of the reset signal generation circuit 16 is connected to the external terminal T4.

The feedback voltage Vf is input to the non-inverting input end (+) of the reset signal generation circuit 16. The comparison voltage REF is input to the inverting input end (−) of the reset signal generation circuit 16. The reset signal generation circuit 16 generates a reset signal SR according to the result of a comparison between the feedback voltage Vf and the comparison voltage REF.

Specifically, when the feedback voltage Vf is lower than the comparison voltage REF, the reset signal generation circuit 16 maintains the reset signal SR at a low level. In contrast, when the feedback voltage Vf exceeds the comparison voltage REF, the reset signal generation circuit 16 maintains the reset signal SR at a high level.

The oscillation circuit 19y generates a clock signal CLK and inputs it to the driver stage 1B (in more detail, a logic circuit 14 to be described later). The clock signal CLK is a pulse signal rising from a low level to a high level at a predetermined oscillation frequency. The detailed configuration of the oscillation circuit 19y will be described later. It should be noted that the oscillation frequency of the clock signal CLK will also be referred to simply as a “pulse frequency” below.

The driver stage 1B generates the drive signals G1 and G2 on the basis of inputs of the clock signal CLK and the reset signal SR, and performs switching drive of the switch output stage HB. More detailed description is as follows.

When detecting the rise of the clock signal CLK, the driver stage 1B sets the drive signal G1 to a high level and the drive signal G2 to a low level such that the output element N1 is turned on and the rectifying element N2 is turned off. In addition, when detecting the rise of the reset signal SR, the driver stage 1B sets the drive signal G1 to a low level and the drive signal G2 to a high level such that the output element N1 is turned off and the rectifying element N2 is turned on.

The specific configuration of the driver stage 1B is as follows. The driver stage 1B includes a logic circuit 14 and a signal generation circuit 15.

The logic circuit 14 is an RS flip-flop including a set input end SET, a reset input end RST, and an output end Q. The set input end SET is connected to the oscillation circuit 19y. The reset input end RST is connected to an output end of the reset signal generation circuit 16. The output end Q is connected to the signal generation circuit 15.

The clock signal CLK is input from the oscillation circuit 19y to the set input end SET. A reset signal is input from the reset signal generation circuit 16 to the reset input end RST. The output end Q inputs a first PWM signal SP1 to the signal generation circuit 15.

The logic circuit 14 generates the first PWM signal SP1 on the basis of the clock signal CLK and the reset signal. When detecting a rising edge of the clock signal CLK to a high level via the set input end SET, the logic circuit 14 raises a logic level of the first PWM signal SP1 to a high level. In addition, when detecting a rising edge of the reset signal to a high level via the reset input end RST, the logic circuit 14 lowers the logic level of the first PWM signal SP1 to a low level.

The signal generation circuit 15 generates the drive signals G1 and G2 on the basis of the first PWM signal SP1. Specifically, when the first PWM signal SP1 is at a high level, the signal generation circuit 15 sets a logic level of the drive signal G1 to a high level and a logic level of the drive signal G2 to a low level. In contrast, when the first PWM signal SP1 is at a low level, the signal generation circuit 15 sets the logic level of the drive signal G1 to a low level and the logic level of the drive signal G2 to a high level.

### <Regarding Switching Operation of Switch Output Stage HB>

As described above, when detecting a rising edge of the clock signal CLK, the first PWM signal SP1 rises to a high level. In addition, when the first PWM signal SP1 rises to a high level, the drive signal G1 rises to a high level, and the drive signal G2 falls to ≈ a low level as described above. At this time, the output element N1 is turned on, and the rectifying element N2 is turned off. Then, the switch voltage Vsw rises from a low level (=GND) to a high level (≈Vin).

As a result, an inductor current IL changes from the state of decreasing to increasing. In response to this, charges according to the inductor current IL are accumulated in the capacitor C1, and the output voltage Vout starts to rise.

Thereafter, when the feedback voltage Vf exceeds the comparison voltage REF, the reset signal SR rises to a high level. Then, the first PWM signal SP1 falls to a low level. Accordingly, the drive signal G1 falls to a low level, and the drive signal G2 rises to a high level. Then, the output element N1 is turned off, and the rectifying element N2 is turned on.

As a result, the inductor current IL changes from the state of increasing to decreasing. In addition, at this time, since the charge of the capacitor C1 is discharged to the ground end GND, the output voltage Vout quickly decreases to the ground potential GND (=0 V). Accordingly, the reset signal SR falls to a low level without delay. In addition, the switch voltage Vsw falls from a high level (≈Vin) to a low level (≈GND). Thereafter, the operation similar to the above is repeated.

<Regarding Configuration of Oscillation Circuit 19y>

FIG. 2 is a diagram for depicting a configuration of the oscillation circuit 19y. The oscillation circuit 19y includes a first reference voltage generation circuit 21, a ramp voltage generation circuit 22y, and a comparator 23.

The first reference voltage generation circuit 21 generates a first reference voltage Vr1. The first reference voltage Vr1 is a predetermined constant voltage.

The ramp voltage generation circuit 22y generates a ramp voltage Vrmp on the basis of the first reference voltage Vr1. The ramp voltage Vrmp alternately repeats up and down in a predetermined sawtooth wave form. The details of the ramp voltage generation circuit 22y and the ramp voltage Vrmp will be described later.

The ramp voltage Vrmp is input to a first input end of the comparator 23. In addition, the first reference voltage Vr1 is input to a second input end of the comparator 23. The comparator 23 outputs the clock signal CLK as a result of a comparison between the ramp voltage Vrmp and the first reference voltage Vr1.

### <Regarding Ramp Voltage Generation Circuit 22y and Ramp Voltage Vrmp>

The ramp voltage generation circuit 22y includes a second reference voltage generation circuit 24, a ramp current generation circuit 25y, and a current-voltage conversion circuit 28.

The second reference voltage generation circuit 24 generates a second reference voltage Vr2 on the basis of the first reference voltage Vr1. Detailed description is as follows. The second reference voltage generation circuit 24 includes a resistor R3 and a resistor R4. A first end of the resistor R3 receives an input of the first reference voltage Vr1. A second end of the resistor R3 is connected to a first end of the resistor R4. A second end of the resistor R4 is connected to the ground end GND.

The second reference voltage Vr2 is generated at the connection node between the resistor R3 and the resistor R4. The second reference voltage Vr2 is a voltage obtained by dividing the first reference voltage Vr1 and the ground voltage GND by the resistor R3 and the resistor R4.

The ramp current generation circuit 25y generates a ramp current Irmp on the basis of the second reference voltage Vr2. Detailed description is as follows. The ramp current generation circuit 25y includes an operational amplifier 26y, a switch element N4, a resistor R5, and a current mirror circuit 27.

The operational amplifier 26y includes a non-inverting input end (+), an inverting input end (−), and an output end. The non-inverting input end (+) of the operational amplifier 26y is connected to the connection node between the resistor R3 and the resistor R4. That is, the non-inverting input end (+) of the operational amplifier 26y receives an input of the second reference voltage Vr2. The output end of the operational amplifier 26y is fed back and input to its own inverting input end (−) via the switch element N4. A node voltage V1 to be described later is input to the inverting input end (−) as a feedback input.

The switch element N4 is an N-channel MOSFET. The output end of the operational amplifier 26y is connected to a gate end of the switch element N4. A drain end of the switch element N4 is connected to the current mirror circuit 27 (more specifically, a drain end of a switch element P1 to be described later). A source end of the switch element N4 is connected to the inverting input end (−) of the operational amplifier 26y together with a first end of the resistor R5. A second end of the resistor R5 is connected to the ground end GND. The node voltage V1 is generated at the connection node between the resistor R5 and the source end of the switch element N4.

The voltage between both ends of the resistor R5 (=node voltage V1) changes according to the gate voltage (=output voltage of the operational amplifier 26y) of the switch element N4. More specifically, the operational amplifier 26y drives and controls the switch element N4 such that the second reference voltage Vr2 and the node voltage V1 coincide with each other (imaginary short-circuit) by the feedback input of the node voltage V1. Accordingly, a current I1 according to the ground voltage GND and the resistance value of the resistor R5 is generated.

The current mirror circuit 27 generates the ramp current Irmp as a mirror current obtained by mirroring the current I1. Detailed description is as follows.

The current mirror circuit 27 includes switch elements P1 and P2. Both of the switch elements P1 and P2 are P-channel MOSFETs. A source end of the switch element P1 is connected to an output end of a power supply voltage Vdd together with a source end of the switch element P2. A drain end of the switch element P1 is connected to a drain end of the switch element N4 together with its own gate end and a gate end of the switch element P2.

A drain voltage according to the current I1 is generated at the drain end of the switch element N4. The drain voltage is input to the gate end of each of the switch elements P1 and P2. Accordingly, the current I1 according to the power supply voltage Vdd and the ramp current Irmp corresponding to the current I1 flow.

The current-voltage conversion circuit 28 converts the ramp current Irmp into a voltage to generate the ramp voltage Vrmp. Detailed description is as follows. The current-voltage conversion circuit 28 includes a capacitor C2 and a switch element N3.

A first end of the capacitor C2 is connected to the first input end of the comparator 23 together with a drain end of the switch element P2. A second end of the capacitor C2 is connected to the ground end GND.

A drain voltage according to the ramp current Irm is generated at the drain end of the switch element P2. The capacitor C2 receives the drain input voltage at its own first end and generates the ramp voltage Vrmp obtained by smoothing the drain voltage.

The switch element N3 is an N-channel MOSFET. A gate end of the switch element N3 is connected to an output end of the comparator 23. A drain end of the switch element N3 is connected to the drain end of the switch element P2 together with the capacitor C1. A source end of the switch element N3 is connected to the ground end GND.

The switch element N3 receives an input of the clock signal CLK at its own gate end. The switch element N3 changes between a saturated state (ON state) and a cut-off state (OFF state) according to the clock signal CLK.

For example, when the clock signal CLK is at a high level, the switch element N3 becomes a saturated state. At this time, a channel is formed between the drain end and the source end of the switch element N3, and a current path is formed. That is, when the clock signal CLK rises to a high level, the ramp current Irmp flows to the ground end GND via the switch elements P2 and N3. At this time, the charge of the capacitor C2 is sharply discharged. Therefore, the ramp voltage Vrmp sharply drops at the same time as the rise of the clock signal CLK.

In contrast, when the clock signal CLK is at a low level (when it is less than the ON threshold voltage of the switch element N3), the switch element N3 becomes a cut-off state. At this time, the channel between the drain end and the source end of the switch element N3 disappears, and the current path disappears. That is, when the clock signal CLK falls to a low level, the ramp current Irmp flows to the ground end GND via the switch element P2 and the capacitor C2. At this time, charges are gradually accumulated in the capacitor C2. Therefore, the ramp voltage Vrmp rises at a predetermined slew rate when the clock signal CLK is at a low level. As described above, the ramp signal generation circuit 25y generates the ramp voltage Vrmp.

### <Consideration on Variation of Input Voltage Vin and ON/OFF Period of First PWM Signal SP1>

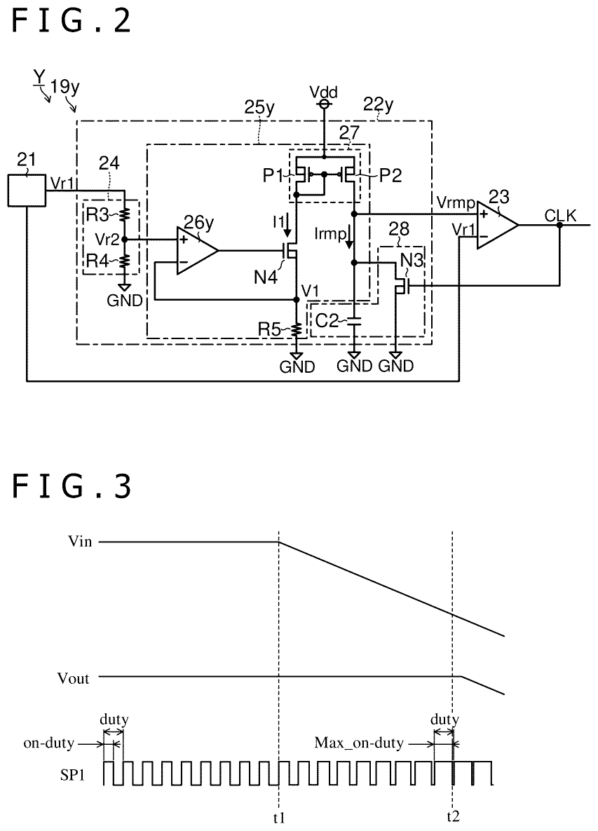

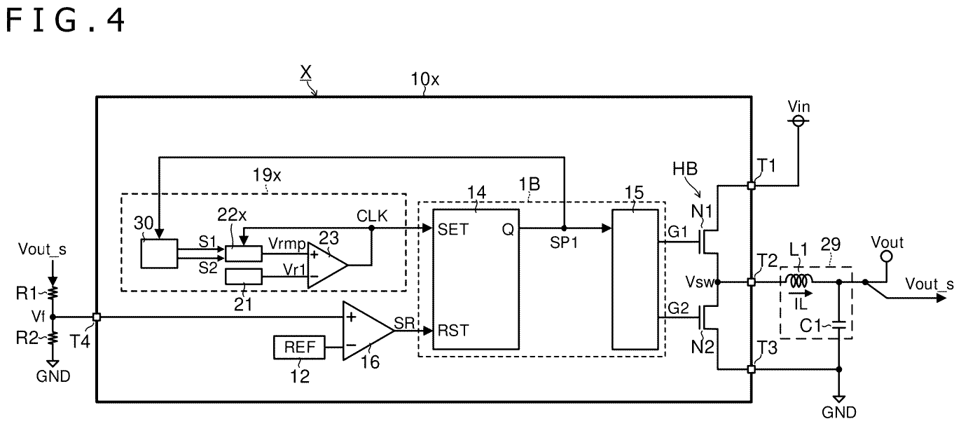

FIG. 3 is a diagram for depicting the input voltage Vin, the output voltage Vout, and the first PWM signal SP1. As depicted in FIG. 3, the input voltage Vin remains constant until predetermined time t1 arrives. Therefore, the first PWM signal SP1 is pulse-driven so as to alternately switch between a high level (first logic level) and a low level (second logic level) at a predetermined period and a predetermined duty ratio.

Here, the power supply device Y is configured to control the duty ratio of the first PWM signal SP1 according to a change in the input voltage Vin to keep the output voltage Vout constant. Detailed description is as follows.

It is assumed that time t1 has arrived and the input voltage Vin has gradually started to decrease thereafter due to some factor. In this case, in order to keep the output voltage Vout constant, the power supply device Y increases the on-duty of the first PWM signal SP1 according to the amount of decrease in the input voltage Vin. The on-duty refers to the ratio of the on-period to the duty ratio.

More specifically, the power supply device Y decreases the value of the comparison voltage REF according to the amount of decrease in the input voltage Vin to lengthen the pulse period of the reset signal. Accordingly, the on-duty of the first PWM signal SP1 becomes longer. As the on-duty of the first PWM signal SP1 becomes longer, the on-period of the output element N1 becomes longer. Therefore, even if the input voltage Vin decreases, the decrease in the output voltage Vout is suppressed.

In contrast, it is assumed that the input voltage Vin continues to rise due to some factor. In this case, in contrast to the case where the input voltage Vin decreases as described above, the power supply device Y decreases the on-duty of the first PWM signal SP1 (that is, increases the off-duty) according to the amount of decrease in the input voltage Vin to keep the output voltage Vout constant.

Specifically, at this time, the power supply device Y increases the value of the comparison voltage REF according to the amount of rise in the input voltage Vin to shorten the pulse period of the reset signal. Accordingly, the on-duty of the first PWM signal SP1 becomes shorter. As the on-duty of the first PWM signal SP1 becomes shorter, the on-period of the output element N1 becomes shorter. Therefore, even if the input voltage Vin rises, the rise of the output voltage Vout is suppressed.

Incidentally, in the case where the input voltage Vin continues to decrease, the on-duty of the first PWM signal SP1 reaches the upper limit value (hereinafter, also referred to as a “max on-duty”). At this time, the off-duty of the first PWM signal SP1 has reached the lower limit value, and the off-duty may not be decreased below this state. That is, the on-duty of the first PWM signal SP1 may not be increased more than the max on-duty.

For example, at time t2 in FIG. 3, the first PWM signal SP1 reaches the max on-duty. Therefore, even though the input voltage Vin continues to decrease after time t2, the first PWM signal SP1 may not further increase the on-duty from the state of the max on-duty. As a result, the decrease in the output voltage Vout may not be suppressed, and the output voltage Vout also decreases according to the decrease in the input voltage Vin.

In addition, in the case where the input voltage Vin continues to rise, the on-duty of the first PWM signal SP1 reaches the lower limit value (hereinafter, also referred to as a “minimum on-duty”) in contrast to the case where the input voltage Vin continues to decrease. The on-duty of the first PWM signal SP1 may not be decreased less than the minimum on-duty. Thus, even though the input voltage Vin continues to rise, the first PWM signal SP1 may not decrease the on-duty less than the minimum on-duty. Accordingly, the rise of the output voltage Vout may not be suppressed, and the output voltage Vout rises according to the rise of the input voltage Vin.

As described above, the first PWM signal SP1 has the on-duty limitations (the max on-duty and the minimum on-duty). Therefore, when a change in the input voltage Vin becomes relatively large, there is a risk that the power supply device Y may not suppress a change in the output voltage Vout due to the limitations of the on-duty.

In response to such a problem, the power supply device X of the present disclosure can suppress the change in the output voltage Vout. The power supply device X according to each embodiment of the present disclosure will be described in detail below. It should be noted that the power supply device X according to each embodiment of the present disclosure includes configurations common to the above-mentioned power supply device Y. Therefore, the same reference signs are assigned to the common configurations, and the description thereof is omitted.

### <Regarding Power Supply Device X According to Present Disclosure>

FIG. 4 is a block diagram for depicting a configuration of the power supply device X according to the present disclosure. As depicted in FIG. 4, the power supply device X is a step-down type DC/DC converter that generates an output voltage Vout from an input voltage Vin and supplies it to a load (not illustrated). The power supply device X has a power supply control device 10x and various discrete components (for example, an inductor L1, a capacitor C1, and resistors R1 and R2) similar to those described above.

The DC output voltage Vout can be obtained by smoothing a switch voltage Vsw by use of a smoothing/rectifying circuit 29 configured with the capacitor C1 and the inductor L1.

<Regarding Power Supply Control Device 10x>

The power supply control device 10x is a semiconductor IC device (what is generally called power supply control IC)). The power supply control device 10x includes external terminals T1 to T4 similar to those described above as a section establishing electrical connection with the outside of the device.

The power supply control device 10x has a switch output stage HB, a comparison voltage generation circuit 12, a reset signal generation circuit 16, and a driver stage 1B which are similar to those described above. In addition to these components, the power supply control device 10x has an oscillation circuit 19x.

The oscillation circuit 19x generates a clock signal CLK and inputs it to a driver stage 1B (more particularly, a logic circuit 14). The oscillation circuit 19x variably controls the pulse period of the clock signal CLK on the basis of a first PWM signal SP1. Detailed description is as follows.

It is assumed that the on-duty of the first PWM signal SP1 has increased to reach the max on-duty. At this time, the oscillation circuit 19x lengthens the pulse period of the clock signal CLK. In contrast, it is assumed that the on-duty of the first PWM signal SP1 has decreased to reach the minimum on-duty. At this time, the oscillation circuit 19x lengthens the pulse period of the clock signal CLK.

Here, as described above, the logic level of the first PWM signal SP1 becomes a high level at the detection timing of the rising edge of the clock signal CLK. Therefore, when the pulse period of the clock signal CLK becomes longer, the pulse period of the first PWM signal SP1 also becomes longer. Accordingly, the on-period of the first PWM signal SP1 can be lengthened without changing the duty ratio. That is, even if the on-period of the first PWM signal SP1 is set to be relatively long, the on-duty of the first PWM signal SP1 becomes difficult to reach the max on-duty. In addition, when the pulse period of the first PWM signal SP1 becomes longer, the on-duty of the first PWM signal SP1 becomes difficult to reach the minimum on-duty even if the off-period of the first PWM signal SP1 is relatively long.

Therefore, it is possible to effectively suppress the decrease in the output voltage Vout according to the decrease in the input voltage Vin. The oscillation circuit 19x will be described in more detail below.

<Regarding Oscillation Circuit 19x>

The oscillation circuit 19x includes a pulse period control circuit 30, a ramp voltage generation circuit 22x, a first reference voltage generation circuit 21, and a comparator 23.

The pulse period control circuit 30 receives an input of the first PWM signal SP1. The pulse period control circuit 30 generates a first duty information signal S1 and a second duty information signal S2 according to the first PWM signal SP1. The first duty information signal S1 and the second duty information signal S2 are generated in such a manner as to reflect the duty state of the first PWM signal SP1. Detailed description is as follows.

The pulse period control circuit 30 generates the first duty information signal S1 such that the first duty information signal S1 becomes equal to or less than a second reference voltage Vr2 in a state where the on-duty of the first PWM signal SP1 has reached the minimum on-duty. In addition, the pulse period control circuit 30 generates the second duty information signal S2 such that the second duty information signal S2 becomes equal to or less than the second reference voltage Vr2 in a state where the on-duty of the first PWM signal SP1 has reached the max on-duty.

The ramp voltage generation circuit 22x receives inputs of the first duty information signal S1 and the second duty information signal S2. The ramp voltage generation circuit 22x generates a ramp voltage Vrmp according to the first duty information signal S1, the second duty information signal S2, and the first reference voltage Vr1.

As described above, the comparator 23 outputs the clock signal CLK as a result of a comparison between the ramp voltage Vrmp and the first reference voltage Vr1.

### <Regarding Pulse Period Control Circuit 30>

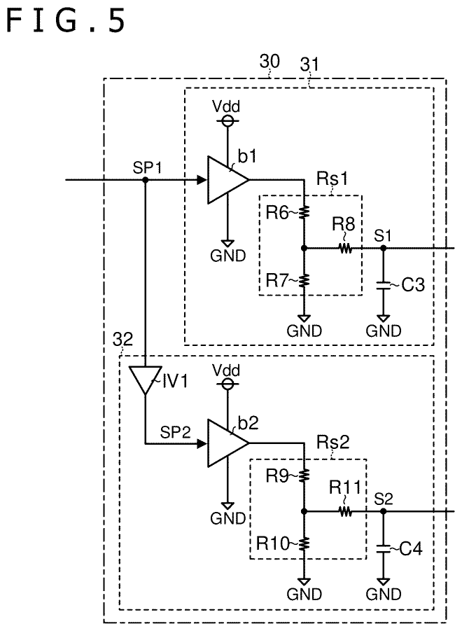

Next, the pulse period control circuit 30 will be described in more detail. FIG. 5 is a diagram for depicting a configuration of the pulse period control circuit 30. As depicted in FIG. 5, the pulse period control circuit 30 includes a first signal generation circuit 31 and a second signal generation circuit 32.

The first signal generation circuit 31 generates the first duty information signal S1 on the basis of the first PWM signal SP1. Detailed description is as follows. The first signal generation circuit 31 includes a buffer circuit b1, resistors R6 to R8, and a capacitor C3.

The buffer circuit b1 receives an input of the first PWM signal SP1, and outputs the first PWM signal SP1 in a state where predetermined buffer processing is applied to the first PWM signal SP1.

A first end of the resistor R6 is connected to an output end of the buffer circuit b1. A second end of the resistor R6 is connected to a first end of the resistor R8 together with a first end of the resistor R7. A second end of the resistor R7 is connected to a ground end GND. A second end of the resistor R8 is connected to a first end of the capacitor C3. A second end of the capacitor C3 is connected to the ground end GND.

When the resistors R6 to R8 are formed as one combined resistor Rs1, the combined resistor Rs1 and the capacitor C3 configure an RC circuit. Therefore, the first PWM signal SP1 subjected to the predetermined buffer processing is smoothed by the combined resistor Rs1 and the capacitor C3 and is output as the first duty information signal S1 that is a DC voltage. That is, the first signal generation circuit 31 is configured to convert the first PWM signal SP1 into the first duty information signal S1, which is a predetermined DC voltage, by the RC circuit.

The second signal generation circuit 32 generates the second duty information signal S2 on the basis of a second PWM signal SP2 (or the first PWM signal SP1). Detailed description is as follows. The second signal generation circuit 32 includes an inverter IV4, a buffer circuit b2, resistors R9 to R11, and a capacitor C4.

The first PWM signal SP1 is input to an input end of the inverter IV4. The inverter IV4 generates the second PWM signal SP2 obtained by inverting the logic level of the first PWM signal SP1.

The buffer circuit b2 receives an input of the second PWM signal SP2 and outputs the second PWM signal SP2 in a state where predetermined buffer processing is applied to the second PWM signal SP2.

A first end of the resistor R9 is connected to an output end of the buffer circuit b2. A second end of the resistor R9 is connected to a first end of the resistor R11 together with a first end of the resistor R10. A second end of the resistor R10 is connected to the ground end GND. A second end of the resistor R11 is connected to a first end of the capacitor C4. A second end of the capacitor C4 is connected to the ground end GND.

When the resistors R9 to R11 are formed as one combined resistor Rs2, the combined resistor Rs2 and the capacitor C4 configure an RC circuit. Therefore, the second PWM signal SP2 subjected to the predetermined buffer processing is smoothed by the combined resistor Rs2 and the capacitor C4 and is output as the second duty information signal S2 that is a DC voltage. That is, the second signal generation circuit 32 is configured to convert the second PWM signal SP2 (or the first PWM signal SP1) into the second duty information signal S2, which is a predetermined DC voltage, by the RC circuit.

<Regarding Ramp Voltage Generation Circuit 22x>

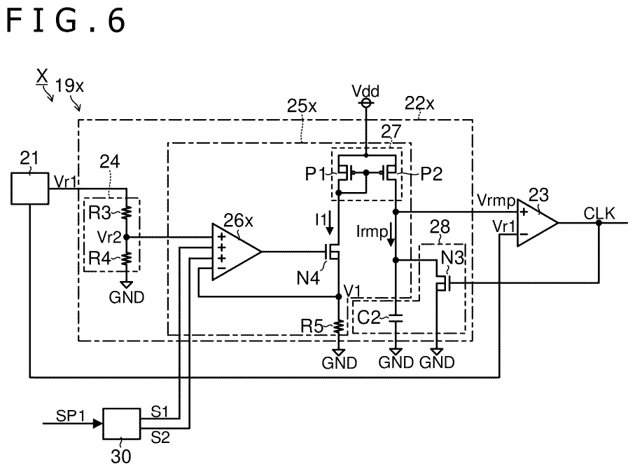

Next, the ramp voltage generation circuit 22x will be described in more detail. FIG. 6 is a diagram for depicting a configuration of the ramp voltage generation circuit 22x. As depicted in FIG. 6, the ramp voltage generation circuit 22x includes resistors R3 and R4 and a current-voltage conversion circuit 28 which are similar to those described above. In addition to these components, the ramp voltage generation circuit 22x includes a ramp current generation circuit 25x.

The ramp current generation circuit 25x includes a switch element N4, a resistor R5, and a current mirror circuit 27 which are similar to those described above. In addition to these components, the ramp current generation circuit 25x includes an operational amplifier 26x.

In the operational amplifier 26x, the second reference voltage Vr2 is input to a first non-inverting input end (+), the first duty information signal S1 is input to a second non-inverting input end (+), the second duty information signal S2 is input to a third non-inverting input end (+), and the node voltage V1 is input to an inverting input end (−). It should be noted that, in FIG. 6, the first non-inverting input end (+) to the third non-inverting input end (+) are depicted in order from the top.

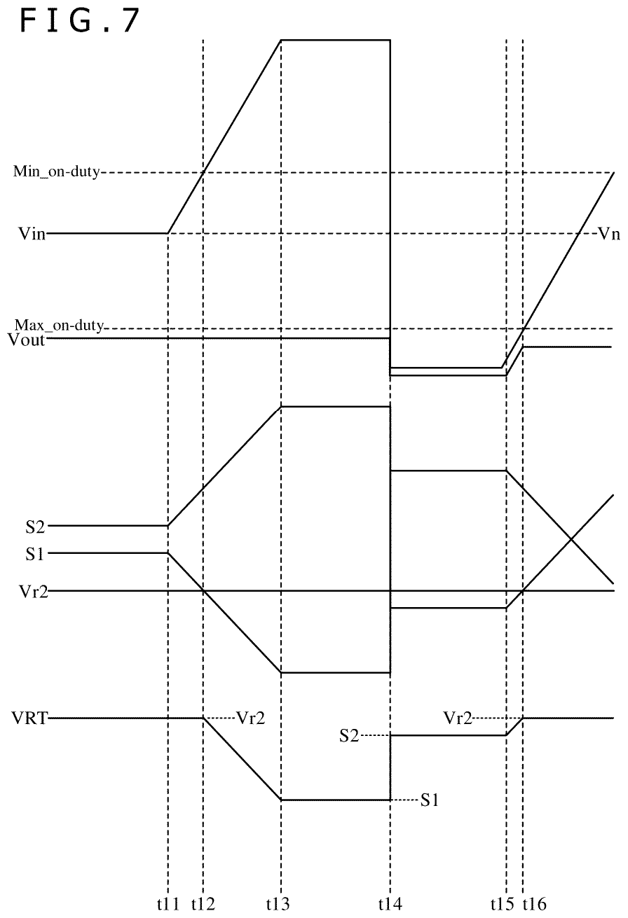

The operational amplifier 26x drives and controls a gate end of the switch element N4 such that the lowest voltage (indicated as a signal VRT in FIG. 7 to be described later) among the second reference voltage Vr2, the first duty information signal S1, and the second duty information signal S2 and the node voltage V1 are imaginarily short-circuited. Detailed description is as follows.

FIG. 7 is a timing chart for depicting a relation between the input voltage Vin and the output voltage Vout. FIG. 7 depicts the input voltage Vin, the output voltage Vout, the first duty information signal S1, the second duty information signal S2, the second reference voltage Vr2, and the signal VRT. It should be noted that the first duty information signal S1 and the second duty information signal S2 depicted in FIG. 7 depict graphs in an ideal state in which output ripples and other components are omitted.

As described above, the signal VRT has the lowest voltage among the second reference voltage Vr2, the first duty information signal S1, and the second duty information signal S2 which are selected by the comparator 23.

First, the displacement of the input voltage Vin from time t11 to time t16 depicted in FIG. 7 will be described. As depicted in FIG. 7, the input voltage Vin remains constant until the arrival of time t11. It is assumed that the value of the input voltage Vin at this time is a reference value Vn. When time t11 arrives, the input voltage Vin starts to rise from the reference value Vn due to some factor. The decrease in the input voltage Vin is stopped at the timing of time t13 when a predetermined period has elapsed from time t11. Then, from time t13 to time t14, the input voltage Vin is in a constant state. When time t14 arrives, the input voltage Vin sharply decreases due to some factor. Then, from time t14 to time t15, the input voltage Vin is in a constant state. Then, after time t15, the input voltage Vin rises again due to some factor.

Next, the first PWM signal SP1, the second PWM signal SP2, and the second reference voltage Vr2 will be described. The duty ratio of the first PWM signal SP1 before the arrival of time t11 is equal to or higher than the minimum duty and equal to or lower than the max duty. Before time t11, since there is no change in the input voltage Vin, there is no change in the duty ratio of the first PWM signal SP1 (not illustrated).

Then, when time t11 arrives, the duty ratio of the first PWM signal SP1 starts to decrease according to the rise of the input voltage Vin. As described above, the decrease in the duty ratio of the first PWM signal SP1 suppresses the decrease in the output voltage Vout. Therefore, even though the input voltage Vin rises after time t11, the output voltage Vout is maintained constant for a predetermined period (referring to FIG. 7, the period until the arrival of time t14).

After time t11, the first duty information signal S1 starts to decrease according to the decrease in the duty ratio of the first PWM signal SP1. In addition, the duty ratio of the second PWM signal SP2 rises according to the decrease in the duty ratio of the first PWM signal SP1. The second duty information signal S2 starts to rise according to the rise of the duty ratio of the second PWM signal SP2.

When a predetermined period of time has elapsed from time t11 and time t12 arrives, the duty ratio of the first PWM signal SP1 reaches the minimum duty. Before the arrival of time t12, the second reference voltage Vr2 has the lowest voltage among the first duty information signal S1, the second duty information signal S2, and the second reference voltage Vr2. That is, before the arrival of time t12, the signal VRT corresponds to the second reference voltage Vr2. In contrast, the first duty information signal S1 falls below the second reference voltage Vr2 at time t12. That is, after time t12, the signal VRT corresponds to the first duty information signal S1 until the arrival of time t14.

When a predetermined period of time has elapsed from time t12 and time t13 arrives, the decrease in the first PWM signal SP1 and the rise of the second PWM signal SP2 are stopped according to the stop of the decrease in the input voltage Vin. Then, the first PWM signal SP1 and the second PWM signal SP2 are maintained constant from time t13 to time t14.

When time t14 arrives, according to the sharp decrease in the input voltage Vin, the second PWM signal SP2 sharply decreases, and the first PWM signal SP1 sharply rises. Then, from time t14 to time t15, the first PWM signal SP1 and the second PWM signal SP2 are maintained constant. Therefore, from time t14 to time t15, the second duty information signal S2 has the lowest voltage among the first duty information signal S1, the second duty information signal S2, and the second reference voltage Vr2. That is, from time t14 to time t15, the signal VRT corresponds to the second duty information signal S2.

When time t15 arrives, the second PWM signal SP2 starts to rise according to the rise of the input voltage Vin. In addition, when time t15 arrives, the first PWM signal SP1 starts to decrease according to the rise of the input voltage Vin. When time t16 arrives, the first PWM signal SP1 reaches the max duty. Then, after time t16, the first PWM signal SP1 decreases, and the second PWM signal SP2 rises.

After time t16, the second reference voltage Vr2 has the lowest voltage among the first duty information signal S1, the second duty information signal S2, and the second reference voltage Vr2. Therefore, after time t16, the signal VRT corresponds to the second reference voltage Vr2 until a predetermined period (omitted in FIG. 7) has elapsed from time t16.

Thus, the ramp voltage generation circuit 22x generates the ramp voltage Vrmp on the basis of the second reference voltage Vr2 until the arrival of time t12. In addition, the ramp voltage generation circuit 22x generates the ramp voltage Vrmp on the basis of the first duty information signal S1 during the period from time t12 to time t14. Further, the ramp voltage generation circuit 22x generates the ramp voltage Vrmp on the basis of the second duty information signal S2 during the period from time t14 to time t16. Further, the ramp voltage generation circuit 22x generates the ramp voltage Vrmp on the basis of the second reference voltage Vr2 after time t16.

As described above, the ramp voltage generation circuit 22x generates the ramp voltage Vrmp on the basis of the lowest voltage among the second reference voltage Vr2, the first duty information signal S1, and the second duty information signal S2.

When the ramp voltage Vrmp is generated on the basis of the second reference voltage Vr2, the pulse period of the first PWM signal SP1 becomes equal to the pulse period when the input voltage Vin has the reference value Vn. In contrast, when the ramp voltage Vrmp is generated on the basis of a voltage lower than the second reference voltage Vr2, the pulse period of the first PWM signal SP1 is longer than the pulse period when the input voltage Vin has the reference value Vn.

As depicted in FIG. 7, from time t11 to time t14, the input voltage Vin rises above the reference value Vn. However, the output voltage Vout is kept constant until the arrival of time t14. In addition, the input voltage Vin sharply decreases to a value below the reference value Vn at time t14. In contrast, the output voltage Vout slightly decreases at time t14. However, the rate of decrease in the output voltage Vout at this time is smaller than the rate of decrease in the input voltage Vin at the same time. Thus, even if the input voltage Vin decreases, the decrease in the output voltage Vout is suppressed.

In the case where the input voltage Vin decreases and the duty ratio of the first PWM signal SP1 rises to the max duty, the second duty information signal S2 becomes the lowest voltage. Therefore, the pulse period of the first PWM signal SP1 becomes longer than that when the input voltage Vin has the reference value Vn. As a result, the on-period of the first PWM signal SP1 can be lengthened while the duty ratio of the first PWM signal SP1 remains at the max duty. Accordingly, it is possible to suppress the decrease in the output voltage Vout while maintaining the duty ratio of the first PWM signal SP1 at the max duty.

In addition, in the case where the input voltage Vin rises and the duty ratio of the first PWM signal SP1 decreases to the minimum duty, the first duty information signal S1 becomes the lowest voltage. Therefore, the pulse period of the first PWM signal SP1 becomes longer than that when the input voltage Vin has the reference value Vn. At this time, if the duty ratio of the first PWM signal SP1 is maintained at the minimum duty, the on-period of the first PWM signal SP1 also becomes longer according to the longer pulse period. That is, the decrease in the output voltage Vout can be suppressed while the duty ratio of the first PWM signal SP1 remains at the minimum duty.

### <Modified Example>

In addition, the present disclosure is not limited to each embodiment described above, and various changes can be made without departing from the gist of the present disclosure. For example, a P-channel MOSFET may be used as the output element N1. In addition, a diode may be used as the rectifying element N2. That is, as for the rectifying system of the power supply device X, not only a synchronous rectifying system but also a diode rectifying system may be adopted. In addition, at least one of the output element N1 and the rectifying element N2 may be externally attached to the power supply control device 10x.

### <Supplementary Note>

An oscillation circuit (19x) disclosed in the specification includes a ramp voltage generation circuit (22x) configured to generate a ramp voltage (Vrmp) on the basis of a first reference voltage (Vr1), and a comparator (23) configured to generate a pulse-driven clock signal (CLK) according to the first reference voltage (Vr1) and the ramp voltage (Vrmp), in which the ramp voltage generation circuit (22x) includes a first signal generation circuit (31) configured to generate a first signal (S1) that rises or falls according to a duty ratio of a first PWM signal (SP1) generated on the basis of a pulse period of the clock signal (CLK), and a second signal generation circuit (32) configured to generate a second signal (S2) that rises or falls in a direction opposite to the first signal (S1) according to the duty ratio of the first PWM signal (SP1), and the ramp voltage generation circuit (22x) is configured to generate the ramp voltage (Vrmp) on the basis of the lowest voltage among a second reference voltage (Vr2) based on the first reference voltage (Vr1), the first signal (S1), and the second signal (S2) (First configuration).

In the oscillation circuit (19x) according to the first configuration, the second signal generation circuit (32) may generate a second PWM signal obtained by inverting the logic level of the first PWM signal (SP1) and may generate the second signal (S2) according to the second PWM signal (Second configuration).

In the oscillation circuit (19x) according to the first or second configuration, the ramp voltage generation circuit (22x) may include a ramp current generation circuit (25x) configured to generate a ramp current (Irmp) on the basis of the lowest voltage among the second reference voltage (Vr2), the first signal (S1), and the second signal (S2), and a current-voltage conversion circuit (28) configured to convert the ramp current into the ramp voltage (Vrmp) (Third configuration).

In the oscillation circuit (19x) according to any one of the first to third configurations, the first signal generation circuit (31) may generate the first signal (S1) such that the first signal (S1) becomes equal to or less than the second reference voltage (Vr2) in a state where an on-duty of the first PWM signal (SP1) reaches a lower limit value, and the second signal generation circuit (32) may generate the second signal (S2) such that the second signal (S2) becomes equal to or less than the second reference voltage (Vr2) in a state where the on-duty of the first PWM signal (SP1) reaches an upper limit value (Fourth configuration).

A power supply device (X) disclosed in the specification includes the oscillation circuit (19x) according to any one of the first to fourth configurations, a PWM signal generation circuit (14) configured to generate a first PWM signal (SP1) on the basis of a pulse period, an output stage (HB) configured to generate a switch voltage (Vsw) that is pulse-driven between a first logical value and a second logical value on the basis of a duty ratio of the first PWM signal (SP1), and a smoothing/rectifying circuit (29) configured to rectify and smooth the switch voltage (Vsw) to generate an output voltage (Vout) (Fifth configuration).

What is claimed is:

1. An oscillation circuit comprising:
a ramp voltage generation circuit configured to generate a ramp voltage on a basis of a first reference voltage; and
a comparator configured to generate a pulse-driven clock signal according to the first reference voltage and the ramp voltage,
wherein the ramp voltage generation circuit includes
a first signal generation circuit configured to generate a first signal that rises or falls according to a duty ratio of a first pulse width modulation signal generated on a basis of a pulse period of the clock signal, and
a second signal generation circuit configured to generate a second signal that rises or falls in a direction opposite to the first signal according to the duty ratio of the first pulse width modulation signal, and
the ramp voltage generation circuit is configured to generate the ramp voltage on a basis of the lowest voltage among a second reference voltage based on the first reference voltage, the first signal, and the second signal.

2. The oscillation circuit according to claim 1,
wherein the second signal generation circuit generates a second pulse width modulation signal obtained by inverting a logic level of the first pulse width modulation signal and generates the second signal according to the second pulse width modulation signal.

3. The oscillation circuit according to claim 1,
wherein the ramp voltage generation circuit further includes
a ramp current generation circuit configured to generate a ramp current on the basis of the lowest voltage among the second reference voltage, the first signal, and the second signal, and
a current-voltage conversion circuit configured to convert the ramp current into the ramp voltage.

4. The oscillation circuit according to claim 1,
wherein the first signal generation circuit generates the first signal such that the first signal becomes equal to or less than the second reference voltage in a state where an on-duty of the first pulse width modulation signal reaches a lower limit value, and
the second signal generation circuit generates the second signal such that the second signal becomes equal to or less than the second reference voltage in a state where the on-duty of the first pulse width modulation signal reaches an upper limit value.

5. A power supply device comprising:
the oscillation circuit according to claim 1;
a pulse width modulation signal generation circuit configured to generate a first pulse width modulation signal on a basis of a pulse period;
an output stage configured to generate a switch voltage that is pulse-driven between a first logical value and a second logical value on a basis of a duty ratio of the first pulse width modulation signal; and
a rectifying/smoothing circuit configured to rectify and smooth the switch voltage to generate an output voltage.
